(19) United States
(12) Patent Application Publication
(10) Pub. No.: US 2024/0388061 A1
(43) Pub. Date: Nov. 21, 2024

(54) OPTOELECTRONIC DEVICES COMPRISING BURIED WIDE BANDGAP HIGH THERMAL CONDUCTIVITY MATERIAL

(71) Applicant: Hewlett Packard Enterprise Development LP, Spring, TX (US)

(72) Inventors: Sagi Mathai, Milpitas, CA (US); Yingtao Hu, Santa Barbara, CA (US)

(21) Appl. No.: 18/320,608

(22) Filed: May 19, 2023

(51) Int. Cl. H01S 5/183; H01S 5/125

(52) U.S. Cl. CPC H01S 5/1835; H01S 5/125; H01S 5/18311

(57) ABSTRACT

Optical devices and methods of fabricating the same are provided. An example of the disclosed optical devices includes an epitaxial mesa formed on a silicon substrate and a single crystal semiconductor material layer formed between the silicon substrate and the epitaxial mesa. The single crystal semiconductor material layer comprises a bandgap that is wider than a bandgap of the epitaxial mesa. The example optical device also includes a semiconductor device layer formed between the single crystal semiconductor material layer and the epitaxial mesa. Examples of the optical devices include vertical injection optical devices, which can include an optically active region. In these examples, the bandgap of the single crystal semiconductor material layer is wider than a bandgap of the optically active region.

### BACKGROUND

A vertical injection laser is a type of semiconductor laser device in which a diode is pumped directly with electrical current perpendicular to the device substrate to create lasing conditions at the diode's p-n junction. Recombination of an electron with a hole occurs in the p-n junction. Due to the drop of the electron from a higher energy level to a lower one, radiation, in the form of an emitted photon is generated. This is referred to as spontaneous emission. Stimulated emission can be produced when a photon induces an electron from a higher energy level to emit another photon. This process is continued and further generates light with the same phase, coherence and wavelength.

### BRIEF DESCRIPTION OF THE DRAWINGS

The present disclosure, in accordance with one or more various implementations, is described in detail with reference to the following figures. The figures are provided for purposes of illustration only and merely depict typical or example implementations.

FIG. 1 illustrates an example optoelectronic device implemented as an active device in accordance with the present disclosure.

FIGS. 2A-2F are schematic cross-sectional views of a sequence of fabricating a optoelectronic device in accordance with the implementations disclosed herein.

FIG. 3 illustrates another example optoelectronic device in accordance with the present disclosure.

FIG. 4 illustrates another example optoelectronic device in accordance with the present disclosure.

FIG. 5 illustrates an flow chart of an example method for fabricating an optical device in accordance with the present disclosure.

Throughout the drawings, identical reference numbers designate similar, but not necessarily identical, elements. The figures are not necessarily to scale, and the size of some parts may be exaggerated to more clearly illustrate the example shown. Further, the relative size of some parts to other parts is not necessarily indicative of a true relative size between the parts. Moreover, the drawings provide examples and/or implementations consistent with the description; however, the description is not limited to the examples and/or implementations provided in the drawings.

### DETAILED DESCRIPTION

The present disclosure is directed to optoelectronic devices having epitaxial layers, such as, but not limited to, edge emitting lasers, vertical cavity surface emitting lasers, light emitting diodes, photodetectors, modulators, optical amplifiers, optical filters, waveguides, etc.

In illustrative examples provided herein, vertical injection optical sources are provided, and more particularly to edge emitting vertical injection lasers. Implementations disclosed herein comprise an epitaxial mesa formed on a substrate that generate an optical signal, such as a lasing mode. The epitaxial mesa may include an optical cavity formed on a substrate and configured to create lasing conditions based on an injection current. For example, the epitaxial mesa comprises an optically active region which can be pumped with electrical current to create the lasing conditions. A thermally conductive region that is electrically insulating can be provided between the substrate and the optical cavity. For example, a single crystal semiconductor material layer can be disposed between the substrate and the epitaxial mesa. The single crystal semiconductor material layer comprises a bandgap that is wider than a bandgap of the optically active region. The wide bandgap semiconductor provides for increased thermal conductivity, increased electrical insulation between the substrate and the epitaxial mesa, and a refractive index that is relatively low at the wavelength of the generated optical signal, as compared to conventional vertical injection laser epitaxial layers.

While the examples described herein are provided with reference to a vertical injection optical source, the present disclosure is not limited to only such implementations. The technology disclosed herein can be applied to any optoelectronic device having epitaxial layers orientated in any direction, such as, but not limited to vertical, horizontal, and/or at any angle with respect to the substrate. Example optoelectronic devices may be passive or active devices and can include, but are not limited to, edge emitting lasers, vertical cavity surface emitting lasers, light emitting diodes, photodetectors, modulators, optical amplifiers, optical filters, waveguides, etc. The epitaxial layers according to the present disclosure can include, but is not limited to, bulk material, quantum wells, quantum dots, 2D materials, nanowires, etc. for realizing either passive or active devices.

Managing the temperature accumulation in the electrically and optically active regions is important for efficient operation of such optical sources. High temperatures can lead to reduced reliability, reduced optical power output, and lower operating speeds. Thus, conventional vertical injection optical sources include epitaxial materials bonded to a substrate such as a Si on insulator (SOI) substrate. Typical vertical injection sources include relatively thick epitaxial materials (e.g., greater than 2 microns thick) that are bonded to a SOI substrate, typically with a thin layer of SiO₂. The thick epitaxial materials results in high material cost. Furthermore, typical vertical injection sources generally pump electrical current into the epitaxial materials using metal electrical contacts. In the typical vertical injection source, these contacts are placed close (for example, 1 to 5 microns) to the epitaxial mesa to reduce the resistance between the electrical contacts and the mesa, which results in optical loss due to light absorption by the metal contacts and higher laser threshold current. Further still, typical vertical injection sources have poor thermal paths between the epitaxial materials and the Si substrate, which leads to increased temperature accumulation in the epitaxial materials (particularly in the active region). As noted above, increased temperature accumulation reduces the reliability of the vertical injection laser, lowers output optical power, and lowers operating speed, such as, but not limited to, electrical bandwidth and/or bit rate.

Some approaches attempt to address the above technical problems. For example, some lateral injection sources attempt to reduce the thickness of the epitaxial layer. While this may reduce material costs, the approach suffers from the poor thermal path to the Si substrate due to the usage of a thermal insulator such as SiO₂ as the bonding material. Furthermore, this approach suffers from complex manufacturing steps. For example, certain layers of the epitaxial materials must be formed using regrowth procedures, while n-and p-doped regions are formed by zinc (Zn) diffusion and Si ion implementation, respectively. Such steps can be complex and costly, and may reduce device yield.

Another disadvantage of conventional vertical injection source is that they use a SOI wafer which includes a low thermal conductivity buried oxide (BOX) layer. One conventional approach replaced the BOX layer with a buried diamond layer to provide increased thermal conductivity. This approach used a) diamond layer formed by chemical vapor deposition (CVD) and having a grain size of 3-5 nm, which provided a thermal conductivity of 12 W/(m×K). Increasing the grain size (e.g., the diamond layer having a grain size of 1 micron or larger) may increase the thermal conductivity to around 300 W/(m×K). The CVD used in the approach provide an amorphous or crystalline material having grain boundaries throughout the diamond layer, which is not a single crystal material. A single crystal material has a continuous crystal lattice throughout its volume and has no grain boundaries. As a result, the thermal conductivity of the CVD deposited buried diamond material in this approach is lower than that achieved by a layer having a single crystal material. Additionally, this approach required a poly-Si layer formed between the Si substrate and the buried diamond layer in order to bond the buried diamond to the Si substrate. The poly-Si layer leads to a reduction in thermal conductivity, especially as compared to the implementations disclosed herein.

Accordingly, some implementations disclosed herein provide for improved vertical injection optical sources having a thin epitaxial mesa and improved thermal conductivity, as compared to conventional vertical injection lasers. For example, some of the implementations disclosed herein provide for an epitaxial mesa that is less than a micron thick, on the order of hundreds of nanometers or less in thickness. However, the epitaxial mesa does not have to be less than a micron in thickness depending on the application. Additionally, implementations disclosed herein comprise a single crystal semiconductor material layer having a bandgap that is wider than a bandgap of an optically active region of the epitaxial mesa. The single crystal semiconductor material layer provides for increased thermal conductivity, which operates to spread heat away from the optically active region. As a result, temperature accumulation in the optically active region is reduced, optical power generated by the epitaxial mesa can be increased, speeds can be increased, and reliability of the optical source is increased. The single crystal semiconductor material layer also has a low refractive index, which results in low optical leakage of the lasing mode into the substrate. As a result, the optical power increases at lower injection currents applied to the first and second electrical contact terminals.

While certain materials are described herein as n-doped or p-doped, implementations are not limited thereto, and the doping polarity may be reversed. For example, the implementations disclosed herein include an epitaxial mesa between first and second semiconductor material layers, where the first semiconductor material layer may be p-doped and the second semiconductor material layer may be n-doped. However, the doping polarity may be switched such that the first semiconductor material layer may be n-doped and the second semiconductor material layer may be p-doped. Additionally, in some instances the epitaxial layers may be undoped, entirely n-doped, entirely p-doped, or include a combination of undoped, n-doped and p-doped layers.

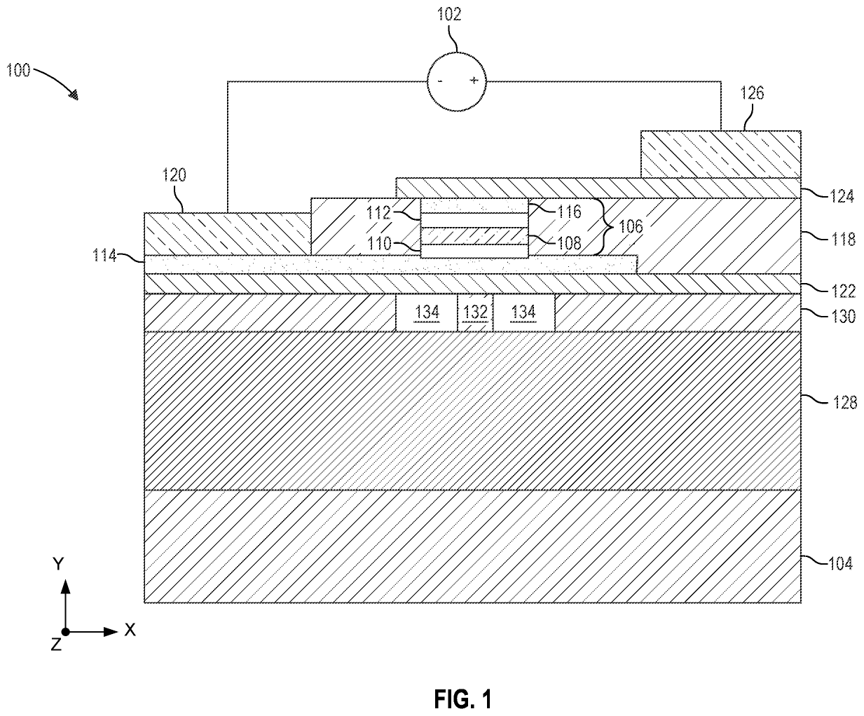

FIG. 1 illustrates an example optoelectronic device implemented as an active device according to an example implementation of the disclosed technology. More particularly, FIG. 1 illustrates an example vertical injection optical source 100 in accordance with the present disclosure. The optical source 100 may comprise an optical cavity, formed on a silicon substrate, that is configured to create lasing conditions based on an injection current. For example, the optical source 100 may be pumped directly with electrical current by an electrical source 102 via electrical contact terminals 120 and 126 to generate a lasing mode within the optical source 100 that oscillates in a direction horizontal to the layers of the optical source 100 (e.g., into and/or out of the page). That is, with reference to the example axes shown in FIG. 1, the x-axis (or x-axis direction) is illustratively shown as extending laterally, the y-axis (or y-axis direction) is illustratively shown as extending vertically, and the z-axis (or z-axis direction) is illustratively shown as extending into and/or out of the page. The axes of FIG. 1 are provided as an example to assist with ease of understanding and as relative orientation between parts. The axes are not intended to limit the disclosure to horizontal or vertical directions.

In the example shown in FIG. 1, optical source 100 is formed on a carrier substrate 104. The carrier substrate 104 may be a Si wafer according to various examples. The optical source 100 comprises an epitaxial mesa 106. The epitaxial mesa 106 can include an optical region 108 sandwiched between a first layer 110 and a second layer 112. In the case of an active optoelectronic device, such as a vertical injection optical source for example, the optical region 108 may be referred to as an optically active region 108. In the case of a passive optoelectronic device, such as a waveguide for example, the optical region 108 may be referred to as an optically passive region 108. While certain layers are described as included in the epitaxial mesa 106 shown in FIG. 1, the technology described herein is not limited to this implementation and the specific layers implemented may be dependent on the desired application and device formed. For example, the epitaxial mesa 106 need not include the optical region 108, and may consist of only the first and second layers.

In the example of FIG. 1 implemented as an active optoelectronic device, the epitaxial mesa 106 can include an optically active region 108 sandwiched between a first separate-confinement heterostructure (SCH) layer 110 and a second SCH layer 112. The first SCH layer 110 and second SCH layer 112 may be undoped or doped and may be the same thickness or different thicknesses (e.g., first SCH layer 110 may be thinner or thicker than the second SCH layer 112). In a case where the first and second SCH layers 110 and 112 are doped, the first SCH layer 110 may be p-doped and the second SCH layer 112 n-doped. The optically active region 108 may generate an optical signal, such as a lasing mode, through spontaneous and/or stimulated emission. For example, the optically active region 108 may comprise quantum dots (DQ), multiple quantum well layers (MQW), quantum-dash structures, or any structure that can generate an optical signal from changes in carrier concentration. The optically active region 108 is generally undoped, but may be delta doped in some implementations. While certain layers are described as included in the epitaxial mesa 106 shown in FIG. 1, the technology described herein is not limited to this implementation. For example, the epitaxial mesa 106 need not include the optically active region 108, and may consist of only the first and second SCH layers.

The optically active region 108 and first and second SCH layers 110 and 112 may be sandwiched between a first semiconductor material layer 114 and a second semiconductor material layer 116. For example, the first semiconductor material layer 114 can be formed on a lower side of the epitaxial mesa 106 and the second semiconductor material layer 116 formed on an upper side of the epitaxial mesa opposite the first semiconductor material layer 114. The first semiconductor material layer 114 and second semiconductor material layer 116 should coincide with the optically active region 108. That is, for example, the first semiconductor material layer 114 and second semiconductor material layer 116 should overlap with optically active region 108 in the x-axis direction and the z-axis direction. In some cases, the second semiconductor material layer 116 and/or first semiconductor material layer 114 may have larger dimensions in the x-and z-axis directions than the optically active region 108. Collectively, the epitaxial mesa 106 and the first and second semiconductor material layers 116 and 114 can be referred to as epitaxial layers. According to various implementations, the epitaxial layers can have a thickness of 1000 nm or less, and in another example, 600 nm or less.

The first semiconductor material layer 114 may comprise a doped Group III-V material, and second semiconductor material layer 116 may comprise a Group III-V material that is oppositely doped relative to the first semiconductor material. For example, the first semiconductor material layer 114 can be p-doped and the second semiconductor material layer 116 can be n-doped. In an example implementation, the Group III-V material comprises at least one of indium gallium arsenide phosphide (InGaAsP), indium phosphide (InP), gallium arsenide (GaAs), gallium nitride (GaN), or the like. In an example implementation, the optically active region 108, first SCH layer 110, second SCH layer 112, second semiconductor material layer 116, and first semiconductor material layer 114 have a combined thickness of 600 nm or less.

The optical source 100 also comprises transparent conductive oxide (TCO) interconnect layers 122, 124. A first TCO interconnect layer 122 is formed between the first semiconductor material layer 114 and the carrier substrate 104 and a second TCO interconnect layer 124 is formed on a side of the second semiconductor material layer 116 opposite the optically active region 108. In various implementations, the TCO interconnect layer 122 may be in direct contact with the first semiconductor material layer 114, and the TCO interconnect layer 124 may be in direct contact with the second semiconductor material layer 116. The TCO interconnect layers 122 should coincide with the first semiconductor material layer 114. That is, for example, the TCO interconnect layers 122 should overlap with the first semiconductor material layer 114 in the x-axis direction and the z-axis direction. Similarly, the TCO interconnect layers 124 should overlap with the second semiconductor material layer 116 in the x-axis direction and the z-axis direction. In some cases, the TCO interconnect layers 122 and 124 may have larger dimensions in the x-and z-axis directions than the first semiconductor material layer 114 and second semiconductor material layer 116, respectively.

The first TCO interconnect layer 122 can function as a bonding layer that bonds the epitaxial layers to a semiconductor device layer 130, instead of an oxide layer (e.g., SiO₂ bonding layer, which function as both a thermal and electrical insulator) as used in conventional vertical injection sources. Further, the TCO interconnect layers 122 and 124 are electrically conductive (whereas conventional oxide layers are insulative), thereby providing for improved lateral current conduction to and from the epitaxial mesa 106 and providing efficient electrical charge exchange. In some implementations, the TCO interconnect layer 122 may be omitted and the epitaxial layers are directly bonded to semiconductor device layer 130 without any intermediate bonding layer. Direct bonding may improve heat transport between the epitaxial mesa and the substrate. Additionally, the first and semiconductor material layers 114 and 116 are relatively thin (for example, 50 to 500 nm), which results in high resistance as current is pumped across the layers. Inclusion of the TCO interconnect layers 122 and 124 lowers the effective resistance between the metal contacts 120 and 126, and the epitaxial mesa 106. Further, the transparent nature of the TCO interconnect layers 122 and 124 provides for minimal optical loss within the TCO interconnect layers 122 and 124. Further still, TCO interconnect layers 122 and 124 have thermal conductivity that is higher than that of a conventionally used oxide bonding layer, and the increased thermal conductivity assists to pull heat away from the epitaxial mesa 106. In some examples, the TCO interconnect layers 122 and 124 may be oppositely doped. For example, the first TCO interconnect layer 122 may be p-doped and the second TCO interconnect layer 124 may be n-doped. The electrical conductivity of the TCO interconnect layers 122 and 124 can be adjusted based on the doping concentration, for example conductivity may be increased through increased dopant concentrations. The interconnect layers 122 and 124 may comprise indium tin oxide (ITO), indium zinc oxide (IZO), or the like.

First and second electrical contact terminals 120 and 126 are electrically connected with the first semiconductor material layer 114 and the second TCO interconnect layer 124, respectively. In the illustrative example of FIG. 1, the first electrical contact terminal 120 and second electrical contact terminal 126 are in direct contact with the first semiconductor material layer 114 and the second TCO interconnect layer 124, respectively. However, intermediate layers may be positioned therebetween if desired for a particular application. In any case, the first electrical contact terminal 120 and second electrical contact terminal 126 are laterally spaced apart from the epitaxial mesa 106 to minimize or completely avoid optical absorption due to the metal contact terminals.

As described above, the epitaxial mesa 106 can be used to generate an optical signal. For example, electrical source 102 can be controlled to inject current into first electrical contact terminal 120, which causes current to flow from first electrical contact terminal 120 to second electrical contact terminal 126. The current causes a carrier concentration change through carrier injection that leads to spontaneous emission and stimulated emission, upon continued current injection, in the optically active region 108, thereby creating lasing conditions. An optical signal (e.g., lasing mode) then oscillates within the optically active region 108 in the z-axis direction. The current flows from first semiconductor material layer 114 to through the epitaxial mesa 106 and into second semiconductor material layer 116. As noted above, the effective lateral resistance between the mesa 106 and contacts 120 and 126 is reduced via the combination of first semiconductor layer 114 and first TCO interconnect layer 122, and second semiconductor layer 116 and second TCO interconnect layer 124. Furthermore, any temperature increase resulting from current flow may be dissipated, at least in part, via first TCO interconnect layer 122 and second TCO interconnect layer 124.

A passivation layer 118 can be formed to encompass the epitaxial mesa 106. The passivation layer 118 encapsulates the second semiconductor material layer 116 as shown in FIG. 1 to provide for device passivation and planarization and electrical contact isolation. Further, passivation layer 118 may also confine oscillation of the optical power within optically active region 108. For example, in the illustrative example shown in FIG. 1, the passivation layer 118 may confine oscillation in the x-axis direction. The passivation layer 118 may be formed of SiO₂, SiₓN_{y} (such as Si₃N₄) or similar material as desired for the particular application. According to various implementations, the passivation layer can have a thickness that is similar to the thickness of the epitaxial layers, as described above. For example, in the case of optical source 100 the passivation layer 118 may have a thickness of 1000 nm or less, and in another example, 600 nm or less.

The first and second SCH layers 110 and 112 can function to confine carriers (e.g., electrons and holes) in the optically active region 108. For example, electrons may be injected into the optically active region 108 from the second semiconductor material layer 116 and holes from the first semiconductor material layer 114, respectively, due to the flow of current. These carriers can be held within the optically active region 108 via the first and second SCH layers 110 and 112. Additionally, first SCH layer 110 and second SCH layer 112 can have a lower refractive index than the optically active region 108, thereby assisting in confining the oscillating optical power in an optical cavity within the epitaxial mesa 106 (e.g., within the optically active region 108). Namely, confining the oscillation of the optical power can be confined in the y-axis direction. As a result of confinement by passivation layer 118, second SCH layer 112, and first SCH layer 110, the optical source 100 can generate a lasing mode that oscillates the z-axis direction in this example.

A single crystal wide bandgap semiconductor layer 128 (sometimes referred to herein as a thermally conductive region) is formed between the carrier substrate 104 and the first interconnect TCO layer 122. As shown in the illustrative example of FIG. 1, single crystal wide bandgap semiconductor layer 128 can be formed directly on the carrier substrate 104. The single crystal wide bandgap semiconductor layer 128 has a bandgap that is at least wider than the bandgap of the optically active region 108. The single crystal wide bandgap semiconductor layer 128 in various implementations is less than or equal to 3 microns thick. In some cases, the single crystal wide bandgap semiconductor layer 128 is between 1 and 3 microns thick. Mechanical rigidity of the optical source 100, according to various examples, is provided mostly via the carrier substrate 104. According to an example implementation, the single crystal wide bandgap semiconductor layer 128 is a silicon carbide (SiC) layer having a single crystal structure; however, other materials are possible such as AlN, BeO, Diamond, etc.

Table 1 below provides various materials that may be implemented in the optical source 100. Table 1 provides example bandgaps, thermal conductivities; and refractive indices at a wavelength of 1.31 microns. Bandgap refers to a difference in energy between a valence band and a conduction band of a solid material (such as an insulator, semiconductor, and the like) that consists of the range of energy values forbidden to electrons in the material. The energy required for electrons and holes to transition from the valance band to the conduction band is the bandgap. A larger value for the bandgap of a material represents a wider bandgap.

TABLE 1

| | | Thermal | Refractive Index |
|---|---|---|---|
| | Bandgap | Conductivity | (at λ = |
| Material | (eV) | (W m\hat{ }−1 K\hat{ }−1) | 1.31 um) |
| GaAs | 1.43 | 55 | 3.41 |
| InP | 1.27 | 68 | 3.19 |
| GaP | 2.25 | 110 | 3.14 |
| Si | 1.11 | 149 | 3.50 |
| GaN | 3.4 | 130 | 2.32 (n_o) |
| AlN | 6 | 180 | 2.17 (n_e) |
| BeO | 10.6 | 265 | 1.72 (n_e) |
| SiC | 3.05 | 490 | 2.61 (n_e) |
| Diamond | 5.47 | 2000 | 2.39 |

The single crystal wide bandgap semiconductor layer 128 may comprise a bandgap that is wider than that of the epitaxial mesa 106. More particularly and as noted above, the single crystal wide bandgap semiconductor layer 128 comprises a bandgap that is wider than that of the optically active region 108. Generally, a wider bandgap translates to reduced optical absorption, lower refractive index, and higher electrical insulation. For example, the single crystal wide bandgap semiconductor layer 128 according to the implementations disclosed herein has a bandgap that provides for high thermal conductivity, electrical insulation, and low refractive index at the lasing mode of the optically active region 108, as compared to a BOX layer of conventional vertical injection lasers.

In an illustrative example, the single crystal wide bandgap semiconductor layer 128 comprises a single crystal structure that has a thermal conductivity that is at least larger than 100 W/(m×K), and more preferably has thermal conductivity that is at least larger than that of Si (e.g., larger than 149 W/(m×K). The high thermal conductivity in the single crystal wide bandgap semiconductor layer operates to pull heat away from the epitaxial mesa 106, thereby reducing temperature accumulation and providing for increased optical power generated by the epitaxial mesa, increased speeds, and increased reliability of the optical source 100. In some examples, the high thermal conductivity of both the single crystal wide bandgap semiconductor layer 128 and TCO interconnect layers 122 can function to reduce temperature accumulation in the epitaxial mesa 106.

In another example, either alone or in combination with the relatively high thermal conductivity, the single crystal wide bandgap semiconductor layer 128 comprises a single crystal structure that has a refractive index that is at least less than that of Si (e.g., less than 3.50 at a 1.31 micron wavelength). Ideally, the single crystal wide bandgap semiconductor layer 128 provides for no optical absorption. That is, the wide bandgap can provide for zero band to band absorption.

In some implementations, an optical device integration region can be formed between the optical cavity and the thermally conductive region. For example, as shown in the illustrative example of FIG. 1, the optical device integration region may be provided as a semiconductor device layer 130 formed between the single crystal wide bandgap semiconductor layer 128 and the first TCO interconnect layer 122. The semiconductor device layer 130 can be used to integrate the optical source 100 with other optical devices and components, which is not possible in the single crystal wide bandgap semiconductor layer 128 directly. This is because, to confine and guide light, the core of an optical waveguide must have a larger refractive index compared to surrounding cladding material. The refractive index of SiC is less than the refractive index of Si which comprises semiconductor device layer 130 and carrier substrate 104, and thus when SiC is used as layer 128 the layer is unable to confine or guide light as a result. Whereas, as shown in FIG. 1, the semiconductor device layer 130 can comprise a waveguide 132 formed between the epitaxial mesa 106 and the single crystal wide bandgap semiconductor layer 128, such that the epitaxial mesa 106 overlaps with the waveguide 132 in a direction perpendicular to the lasing mode. Air gaps 134 can be formed on opposing sides of the waveguide 132, with the remaining portions of the semiconductor device layer 130 functioning as support structures. Optical power generated by the epitaxial mesa 106 can be coupled into the waveguide 132, and confined to the waveguide 132 by air gaps 134, and propagated to other components. Furthermore, the lateral width of the waveguide 132 can be designed so to control confinement of the lasing mode in the epitaxial mesa 106. For example, a narrow waveguide 132 may increase confinement of the optical mode in the epitaxial mesa 106 and a wider waveguide 132 may decrease confinement (e.g., increased optical power in the waveguide 132). In an alternate implementation, the air gaps 134 may be filled with a wide bandgap high thermal conductivity semiconductor with lower refractive index than the waveguide layer 132.

In another example of the device shown in FIG. 1, optical source 100 can be implemented as a passive optoelectronic device (e.g., a waveguide, filter, etc.). The optoelectronic device shown in FIG. 1 implemented as a passive optoelectronic device may be substantially similar to the foregoing description with reference to an active optoelectronic device, except as provided herein.

For example, the epitaxial mesa 106 can include an optically passive region 108 sandwiched between a first layer 110 and a second layer 112. The first and second layers 110 and 112 may be undoped or doped. The optically passive region 108 may comprise bulk material or other structures for providing a desired passive optoelectronic device. For example, in a case where the optoelectronic device is implemented as a waveguide, optically passive region 108 may be a core material for guiding an optical signal along the waveguide and the first and second layers 110 and 112 may be cladding material to confine the optical signal in the optically passive layer. In this example, passivation layer 118 may also be formed of cladding material for optical signal confinement. The optically passive region 108 is generally undoped, but may be delta doped in some implementations. As another example, an optically passive region 108 implemented as a Bragg grating may contain a core material having periodic variations of refractive index across the optically passive region 108. In this case, first and second layers 110 and 112, as well as passivation layer 118, may be implemented as cladding for optical signal confinement.

Additionally, in the case of passive optoelectronic devices, an injection current or power source is not necessary given the passive nature of the devices. As such, according to some examples, a passive optoelectronic device need not comprise electrical source 102, second electrical contact terminal 126, and first electrical contact terminal 120. Furthermore, the TCO interconnect layer 124 may be absent. TCO interconnect layer 122 may be absent as well, but may also be included depending on the bonding technique utilized for bonding the epitaxial layers to the semiconductor device layer 130. For example, as described above, the first TCO interconnect layer 122 can function as a bonding layer that bonds the epitaxial layers to a semiconductor device layer 130, instead of an oxide layer.

In an illustrative example of a passive optoelectronic implementation, the single crystal wide bandgap semiconductor layer 128 comprises a bandgap that is wider than that of the optically passive region 108. Generally, a wider bandgap translates to reduced optical absorption, and lower refractive index. For example, the single crystal wide bandgap semiconductor layer 128 according to the implementations disclosed herein has a bandgap that provides for high thermal conductivity and low refractive index at the guided mode of the optically passive region 108 in the case of a waveguide. However, single crystal wide bandgap semiconductor layer 128 in the case of a passive optoelectronic device is not limited to materials having a bandgap wider than the optically passive region 108. In some cases, depending on the desired application, the bandgap of single crystal wide bandgap semiconductor layer 128 may be narrower than that of the optically passive region 108. In any case, the single crystal wide bandgap semiconductor layer 128 comprises a thermal conductivity that is at least larger than 100 W/(m×K), and more preferably has thermal conductivity that is at least larger than that of Si (e.g., larger than 149 W/(m×K).

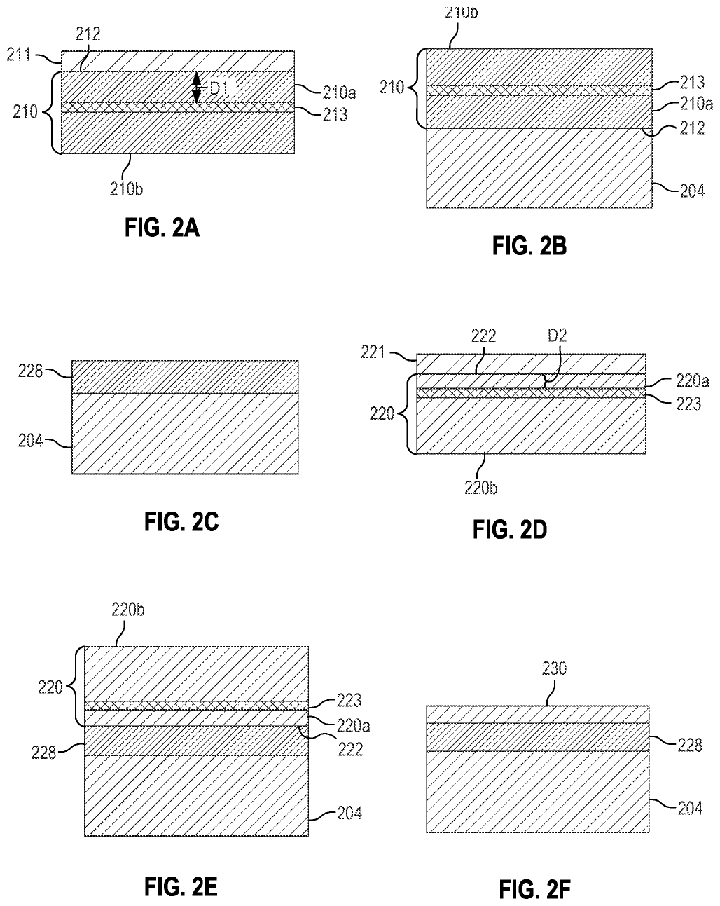

FIGS. 2A-2F are schematic cross-sectional views of a sequence of fabricating an optoelectronic device in accordance with the implementations disclosed herein. FIGS. 2A-2F will be described in reference to the example optical source 100 of FIG. 1; however, the fabrication techniques of FIGS. 2A-2F can be applied to any active or passive optoelectronic device in accordance with the present disclosure.

The fabrication steps of FIGS. 2A-2F depict the steps of a “Smart Cut” process that uses ion implantation followed by separation at the implanted region to provide a single crystal wide bandgap semiconductor layer 228 between a carrier substrate 204 and a semiconductor device layer 230. The single crystal wide bandgap semiconductor layer 228, carrier substrate 204, and semiconductor device layer 230 may be examples of single crystal wide bandgap semiconductor layer 128, carrier substrate 104, and semiconductor device layer 130 of FIG. 1, respectively. Additional layers (such as the other components of FIG. 1) may be formed on the semiconductor device layer 230 using known fabrication techniques, such as but not limited to, deposition, wafer bonding, epitaxy, re-growth, or other fabrication techniques, such as but not limited to, metal organic chemical vapor deposition (MOCVD) and molecular-beam epitaxy (MBE).

FIG. 2A illustrates a single crystal substrate 210 having a first surface 212 and a second surface and a silicon dioxide layer 211 (other materials may be used in place of silicon dioxide, such as photoresist, silicon nitride, etc.) formed on the surface 212. The single crystal substrate 210 is implanted with ions providing an ion implantation region 213 at a first depth D1 in the single crystal substrate 210 from the surface 212. The depth D1 is 3 microns or less according to some examples. In another example, the depth D1 is between at least 1 and at most 3 microns. In an illustrative example, the single crystal substrate 210 is implanted with hydrogen ions (H₊) forming the ion implanted region 213. Other ions may be used as desired for a given fabrication. As a result of ion implantation, the single crystal substrate 210 has a first section 210a and a second section 210b.

Next, as shown in FIG. 2B, the oxide layer 211 is removed and the single crystal substrate 210 is bonded to the carrier substrate 204. For example, the surface 212 is bonded to the carrier substrate 204 such that the first section 210a is adjacent to the carrier substrate 204. In some examples, the surface 212 can be bonded directly to the carrier substrate 204 such that the first section 210a is in direct contact with the carrier substrate 204.

After the single crystal substrate 210 is bonded to carrier substrate 204, the thickness of the single crystal substrate 210 is reduced via a delamination step that removes the second section 210b along the ion implantation region 213. For example, a delaminating process can be used that heats up the single crystal substrate 210, which causes the single crystal substrate 210 to split at the ion implantation region 213. The second section 210b can then be removed, for example, by peeling, lifting or pushing it off, etc. This results in the structure illustrated in FIG. 2C, in which the first section 210a becomes the single crystal wide bandgap semiconductor layer 228. In this way, the thickness of the single crystal wide bandgap semiconductor layer 228 can be provided through control of the implantation depth of ions 213. At this point, the second section 210b may be reused to repeat the process described above to form a single crystal wide bandgap semiconductor layer 228 on another carrier wafer 204. Alternatively, the single crystal substrate 210 may be grinded and polished to leave behind single crystal wide bandgap semiconductor layer 228. This approach is an alternative to the “Smart Cut” process described above.

A similar process is performed to form the semiconductor device layer 230 on single crystal wide bandgap semiconductor layer 228, as shown in FIGS. 2D-2E. FIG. 2D shows substrate 220 having a first surface 222 and a second surface and a silicon dioxide layer 221 formed on the surface 222. The substrate 220 in various examples is a silicon substrate. The substrate 220 is implanted with ions forming an ion implantation region 223 at a depth D2 in the substrate 220 from the surface 222. The depth D2 is 3 micron or less according to some examples. In an illustrative example, the substrate 220 is implanted with hydrogen ions (H₊) forming a ion implantation region 223. Other ions may be used as desired for a given fabrication. As a result of ion implantation, the substrate 220 has a first section 220a and a second section 220b.

Next, as shown in FIG. 2E, the silicon dioxide layer 221 is removed and the substrate 220 is bonded to the single crystal wide bandgap semiconductor layer 228. For example, the surface 222 can be bonded to the single crystal wide bandgap semiconductor layer 228 such that the first section 220a is adjacent to the single crystal wide bandgap semiconductor layer 228. In one example, the surface 222 can be bonded directly to the single crystal wide bandgap semiconductor layer 228 such that the first section 220a is in direct contact with the single crystal wide bandgap semiconductor layer 228.

After the substrate 220 is bonded to single crystal wide bandgap semiconductor layer 228, the thickness of the substrate 220 is reduced via a delaminate step that removes (e.g., exposes) the second section 220b along the ion implantation region 223. This results in the structure illustrated in FIG. 2F, in which the first section 220a becomes the semiconductor device layer 230. Further fabrication techniques, such as but not limited to, etching, photolithography, and so on can be used to form interconnects to other components for and/or from other components in the semiconductor device layer 230 for device integration. For example, waveguide 132 and air gaps 134 of FIG. 1 can be formed in semiconductor device layer 230 using etching techniques.

Alternatively, reducing the thickness of the single crystal substrate 210 or substrate 220 can comprise more conventional steps of lapping and polishing. As is recognized by those familiar with this art, however, the SiC-reducing step (or steps) need to be consistent with the remainder of the device manufacturing steps. Furthermore, separation by implantation of oxygen (SIMOX) can be used to reduce the thickness of the substrates. SIMOX uses implantation of oxygen to a determined depth and then the structure is heated up to produce SiO₂ from the implanted oxygen. Similar to the example of FIGS. 2A-2F, the undesired portion can be removed at the implantation depth. Further still, the separation can be carried out using wet etching in hydrofluoric acid. Hydroflouric acid will dissolve the SiO2 layer.

Another alternative to reduce the thickness of the single crystal substrate 210 or substrate 220 can comprise chemical mechanical polishing and/or dry etching, or combinations of all methods mentioned above.

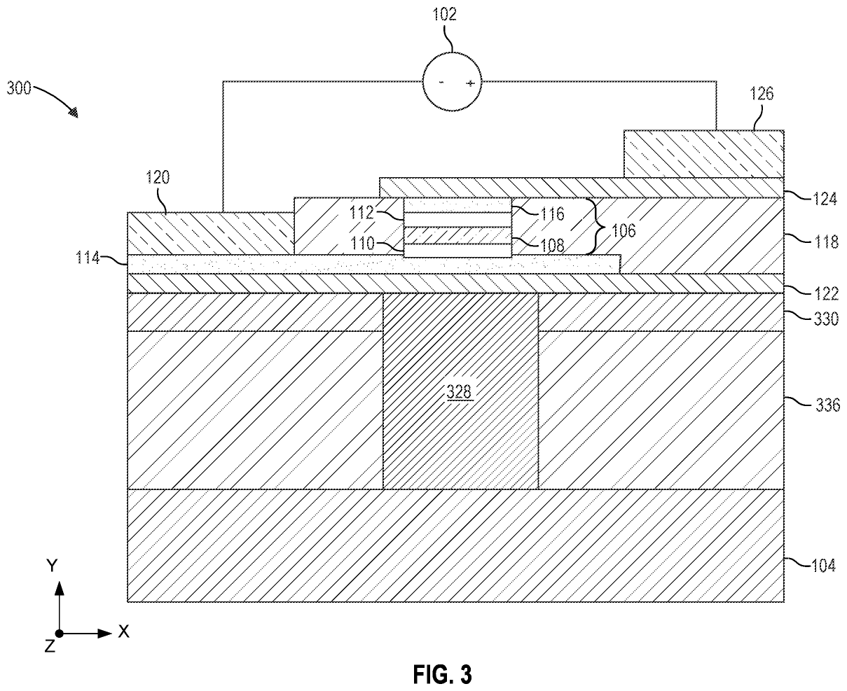

FIG. 3 illustrates another example optoelectronic device in accordance with the present disclosure. More particularly, FIG. 3 illustrates another example vertical injection optical source 300, which may be substantially similar to optical source 100 of FIG. 1. Thus, like reference numbers used in FIG. 3 represent those structures and components described above in reference to one or more of FIG. 1. For example, vertical injection optical source 300 comprises epitaxial layers (including epitaxial mesa 106) between TCO interconnect layers 122 and TCO interconnect layers 124. The epitaxial mesa 106 is formed on a carrier substrate 104. Further, as described above in connection with FIG. 1, the device shown in FIG. 3 may be implemented as a passive optoelectronic device, for example, where epitaxial mesa 106 comprises an optically passive region.

Referring now to an example where the device of FIG. 3 is an active optoelectronic device, vertical injection optical source 300 also includes a BOX layer 336 grown on carrier substrate 104. In an example, BOX layer 336 may comprise silicon dioxide (SiO₂). A section of the BOX layer 336 directly below the epitaxial mesa 106 is removed forming a trench in which a wide bandgap crystalline semiconductor material 328 is deposed therein. Wide bandgap crystalline semiconductor material 328 may be another example of a thermally conductive region. The wide bandgap crystalline semiconductor material 328 can be formed in the trench so to completely fill the trench. The wide bandgap crystalline semiconductor material 328 extends in the x-axis direction so to at least overlap with the epitaxial mesa 106 in the x-axis direction. The width of the wide bandgap crystalline semiconductor material 328 may be wider in the x-axis and/or z-axis direction than the epitaxial mesa 106. A semiconductor device layer 330 is formed between BOX layer 336 and the TCO interconnect layers 122. Semiconductor device layer 330 provides for integration with downstream components, similar to semiconductor device layer 130 of FIG. 1. While FIG. 3 does not illustrate a waveguide, a waveguide could be integrated into semiconductor device layer 330 at other locations of the vertical injection optical source 300.

The material used for wide bandgap crystalline semiconductor material 328 may be similar to single crystal wide bandgap semiconductor layer 128, except that it may not be feasible to deposit a single crystal structure within the trench of the BOX layer 336. In some examples, the wide bandgap crystalline semiconductor material 328 comprises has a thermal conductivity that is at least larger than 100 W/(m×K), and more preferably has thermal conductivity that is at least larger than that of Si (e.g., larger than 149 W/(m×K)), the wide bandgap crystalline semiconductor material 328 comprises a single crystal structure that has a refractive index that is at least less than that of Si (e.g., less than 3.50 at a 1.31 micron wavelength).

As a result, an amorphous crystalline material may be used for wide bandgap crystalline semiconductor material 328 that has a bandgap that is wider than the bandgap of optically active region 108. According to some examples, the wide bandgap crystalline semiconductor material 328 may be amorphous-SiC deposited by plasma enhanced chemical deposition (PECVD), with a thermal conductivity between, but not limited to, 130-160 W/(m×K). Wide bandgap crystalline semiconductor material 328 may be deposited using any known techniques, such as but not limited to, chemical vapor deposition (CVD), molecular beam epitaxy (MBE), atomic layer deposition (ALD), sputtering, etc.

As noted above, the wide bandgap crystalline semiconductor material 328 provides for improved thermal conductivity, low refractive index, reduced optical absorption, and higher electrical insulation due to the relatively wider bandgap. For example, the wide bandgap crystalline semiconductor material 328 provides for a local (e.g., constrained by the BOX layer 336) and direct thermal path, below the epitaxial mesa 106, to the carrier substrate 104 for dissipating heat from the epitaxial mesa 106. That is, for example, heat can be pulled directly through the wide bandgap crystalline semiconductor material 328 without extending in a lateral x-axis direction. Additionally, the layers in vertical injection optical source 300 may be used for optical functionality. For example, semiconductor layer 130 (and 330) may provide optical functionality through, for example but not limited to, waveguiding, tailoring optical mode shape and effective refractive index, distributed Bragg reflectors, subwavelength gratings, etc.

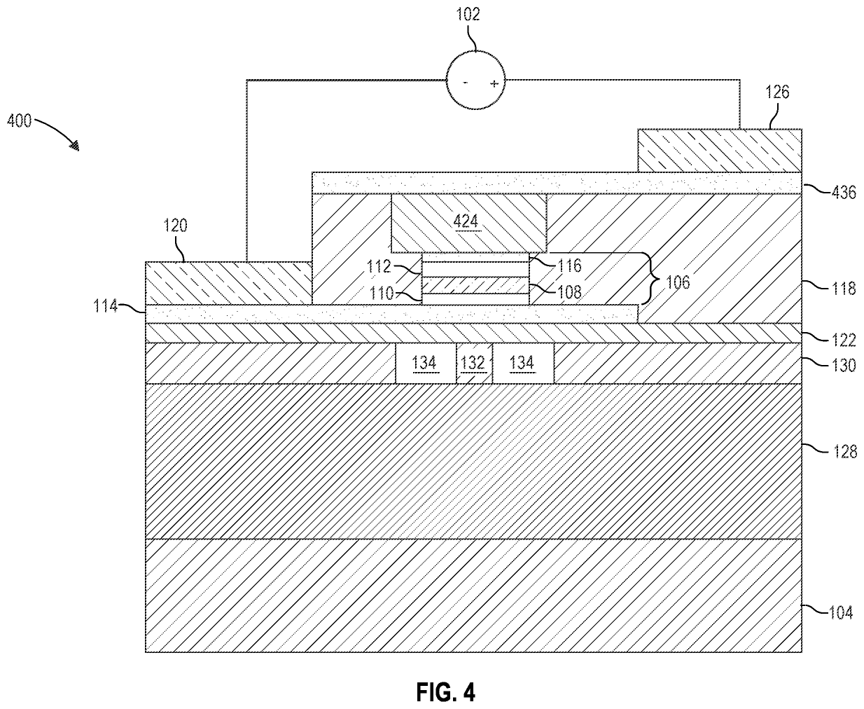

FIG. 4 illustrates another example optoelectronic device in accordance with the present disclosure. More particularly, FIG. 4 illustrates another example vertical injection optical source 300, which may be substantially similar to optical source 100 of FIG. 1. Thus, like reference numbers used in FIG. 4 represent those structures and components described above in reference to one or more of FIG. 1. For example, vertical injection optical source 400 comprises epitaxial layers (including epitaxial mesa 106) formed on first TCO interconnect layers 122, which are formed on the semiconductor device layer 130, single crystal wide bandgap semiconductor layer 128, and carrier substrate 104. Further, as described above in connection with FIG. 1, the device shown in FIG. 4 may be implemented as a passive optoelectronic device, for example, where epitaxial mesa 106 comprises an optically passive region.

Referring now to an example where the device of FIG. 4 is an active optoelectronic device, Vertical injection optical source 400 includes second TCO interconnect layer 424 provided directly above the epitaxial mesa 106. Second TCO interconnect layer 424 is in direct contact with the second semiconductor material layer 116 of epitaxial mesa 106, but, unlike optical source 100, need not extend all the way to the second electrical contact terminal 126. Instead, second TCO interconnect layer 424 is thicker than TCO interconnect layers 124 to act as a buffer layer, thereby increasing the distance between the metal of second electrical contact terminal 126 (when 126 is placed on top of 424) and the epitaxial mesa 106. This may assist to reduce the amount of optical power absorbed by the second electrical contact terminal 126. In another example, second TCO interconnect layer 424 can extend horizontally such that second electrical contact terminal 126 overlaps with second TCO interconnect layer 424 in the vertical direction. As another example, second electrical contact terminal 126 may be positioned on top of second TCO interconnect layer 424.

Additionally, vertical injection optical source 400 includes an optional amorphous semiconductor or metal layer 436. This is an optional layer, and need not be included in the vertical injection optical source 400. In some examples, optional amorphous semiconductor layer 436 may be doped (e.g., n-doped) to increase electrical conductivity between second electrical contact terminal 126 and epitaxial mesa 106 via second TCO interconnect layer 424. Layer 436 may also be used to displace contact 126 laterally away from the mesa 106.

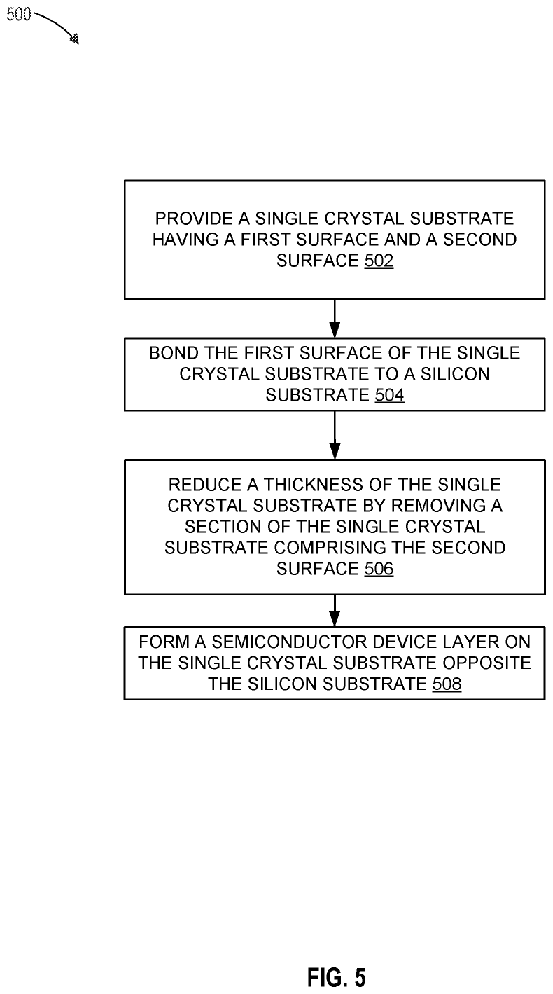

FIG. 5 illustrates a flow chart of an example method 500 for fabricating an optical device in accordance with the present disclosure. The method 500 can be performed to fabricate a vertical injection optical source, as described above. Alternatively, method 500 can be performed to fabricate other active or passive photonic devices, such as but not limited to, photodetectors, modulators, filters, waveguides, etc. Thus, while FIGS. 1-4 are described with reference to a vertical injection optical source, the implementations disclosed herein are not limited to optical sources, but may provide for other passive or active optical devices.

At block 502, a single crystal substrate is provided. The single crystal substrate has a first surface and a second surface. For example, as described in connection with FIG. 2A, a single crystal substrate 210 can be provided that has a first surface 212 and a second surface.

At block 504, the first surface of the single crystal substrate is bonded to a silicon substrate. For example, as described in connection with FIGS. 2A and 2B, the single crystal substrate 210 can be implanted with ions at a first depth D1 from the surface 212, which forms the implanted layer 213. The single crystal substrate 210 can then be bonded to a silicon substrate 204 at the first surface 212.

At block 506, a thickness of the single crystal substrate is reduced by removing a section of the single crystal substrate comprising the second surface. For example, as described in connection with FIGS. 2A and 2B, the thickness of the single crystal substrate 210 can be reduced, for example, by delaminating the section 210b along the ion implantation region. In various examples, reducing the thickness may be performed after bonding the single crystal substrate to a silicon substrate, while in another example reducing the thickness may be performed before bonding if desired.

At block 508, a semiconductor device layer is formed on the single crystal substrate opposite the silicon substrate. For example, as described in connection with FIGS. 2D-2F, a semiconductor device layer 230 can be formed on a surface of the single crystal substrate 228 exposed following reducing the thickness. That is, after substrate 220 is bonded to single crystal wide bandgap semiconductor layer 228, the thickness of the substrate 220 is reduced via a delaminate step that removes (e.g., exposes) the second section 220b along the ion implantation region 223. This results in the first section 220a becoming the semiconductor device layer 230.

Process 500 may include additional operations that can be performed to form the semiconductor device layer. For example, process 500 may include providing a semiconductor device substrate having a first surface and a second surface; reducing a thickness of the semiconductor device substrate by removing a section of the semiconductor device substrate comprising the second surface; and bonding the first surface of the semiconductor device substrate to the single crystal substrate. Examples of these instructions are described above in connection with FIGS. 2D-2F.

Each of the processes, methods, and algorithms described in the preceding sections may be embodied in, and fully or partially automated by, code components executed by one or more computer systems or computer processors comprising computer hardware. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example implementations. The performance of certain of the operations or processes may be distributed among computer systems or computers processors, not only residing within a single machine, but deployed across a number of machines.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. An optoelectronic device comprising:
a silicon substrate;
an epitaxial mesa formed on the silicon substrate;
a single crystal semiconductor material layer formed on the silicon substrate and between the silicon substrate and the epitaxial mesa, wherein the single crystal semiconductor material layer comprises a bandgap that is wider than a bandgap of the epitaxial mesa; and
a semiconductor device layer formed between the single crystal semiconductor material layer and the epitaxial mesa.

2. The optoelectronic device of claim 1, wherein the epitaxial mesa comprises an optically active region, wherein the bandgap of the single crystal semiconductor material layer is wider than a bandgap of the optically active region.

3. The optoelectronic device of claim 1, wherein the epitaxial mesa comprises an optically passive region.

4. The optoelectronic device of claim 1, wherein the single crystal semiconductor material layer comprises single crystal silicon carbide.

5. The optoelectronic device of claim 1, wherein the single crystal semiconductor material layer comprises a thermal conductivity that is greater than 100 W/(m×K).

6. The optoelectronic device of claim 4, wherein a refractive index of the single crystal semiconductor material layer is less than 3.5 at a wavelength emitted by the optically active region.

7. The optoelectronic device of claim 1, wherein the semiconductor device layer comprises at least one of a waveguide, a Bragg reflector, a grating, formed underneath the epitaxial mesa.

8. The optoelectronic device of claim 1, further comprising:
a first transparent conductive oxide (TCO) interconnect layer formed between the semiconductor device layer and the epitaxial mesa; and
a second TCO interconnect layer formed on the epitaxial mesa opposite the silicon substrate.

9. The optoelectronic device of claim 8, wherein at least one of the first TCO interconnect layer and the second TCO interconnect layer comprises one of indium tin oxide and indium zinc oxide.

10. The optoelectronic device of claim 1, wherein the optically active region comprises one or more layers of bulk material, quantum dots, quantum wells, quantum-dash structures, and nanowires.

11. The optoelectronic device of claim 10, further comprising:
a first semiconductor material layer formed between the semiconductor device layer and the optically active region; and
a second semiconductor material layer formed on the optically active region opposite the first semiconductor material layer,
wherein the epitaxial mesa comprises:
a first separate-confinement heterostructure (SCH) layer formed between the first semiconductor material layer and the optically active region, and
a second SCH layer formed between the optically active region and the second semiconductor material layer,
wherein at least one of the first semiconductor material layer and the second semiconductor material layer comprises a Group III-V material.

12. The optoelectronic device of claim 11, wherein the first semiconductor material layer is bonded directly onto the semiconductor device layer.

13. The optoelectronic device of claim 1, further comprising a buried oxide layer formed between the semiconductor device layer and the silicon substrate, the buried oxide layer is adjacent to the single crystal device layer, wherein the single crystal device layer comprises at least one of a single crystal silicon carbide, crystalline silicon carbide and an amorphous silicon carbide.

14. The optoelectronic device of claim 1, wherein the single crystal semiconductor material layer is formed directly on the silicon substrate.

15. An optical device, comprising:
an optical cavity configured to create lasing conditions based on an injection current, the optical cavity formed on a silicon substrate;
a thermally conductive region provided between the silicon substrate and the optical cavity, wherein the thermally conductive region is electrically insulating; and
an optical device integration region formed between the optical cavity and the thermally conductive region.

16. The optical device of claim 15, wherein the thermally conductive region comprises single crystal silicon carbide.

17. The optical device of claim 15, wherein the thermally conductive region comprises a thermal conductivity that is greater than 100 W/(m×K).

18. The optical device of claim 15, wherein the thermally conductive region is directly between the silicon substrate and the optical cavity.

19. A method for fabricating a vertical injection optical source, the method comprising:
providing a single crystal substrate having a first surface and a second surface;
bonding the first surface of the single crystal substrate to a silicon substrate;
reducing a thickness of the single crystal substrate by removing a section of the single crystal substrate comprising the second surface; and
forming a semiconductor device layer on the single crystal substrate opposite the silicon substrate.

20. The method of claim 19, wherein reducing the thickness of the single crystal substrate comprising:
implanting hydrogen ions into the single crystal substrate at a depth from the first surface of the single crystal substrate, the hydrogen ions being between a first section and a second section of the single crystal substrate, the first section comprising the first surface and the second section comprising the second surface; and
after bonding the first surface of the single crystal substrate to the silicon substrate, delaminating the second section of the single crystal substrate to remove the second section of the single crystal substrate.
